(19) United States
(12) Patent Application Publication
(10) Pub. No.: US 2020/0135948 A1
(43) Pub. Date: Apr. 30, 2020

(54) SOLAR CELL AND SOLAR CELL MODULE

(71) Applicant: KANEKA CORPORATION, Osaka (JP)

(72) Inventors: Masanori KANEMATSU, Settsu-shi (JP); Hitoshi TAMAI, Settsu-shi (JP); Daisuke ADACHI, Settsu-shi (JP)

(73) Assignee: KANEKA CORPORATION, Osaka (JP)

(21) Appl. No.: 16/729,928

(22) Filed: Dec. 30, 2019

Related U.S. Application Data
(63) Continuation of application No. PCT/JP2018/020771, filed on May 30, 2018.

(30) Foreign Application Priority Data
Jul. 3, 2017 (JP) 2017-130575

(51) Int. Cl. H01L 31/0224

(52) U.S. Cl. CPC H01L 31/022441; H01L 31/0747; H01L 31/022466

(57) ABSTRACT

A back contact solar cell is suppressed in decrease of yield due to warp of a semiconductor substrate or short circuit of electrodes, and includes a semiconductor substrate; a semiconductor layer of a first conductivity type and a first electrode layer, sequentially laminated on a part of the back surface of the semiconductor substrate; and a semiconductor layer of a second conductivity type and a second electrode layer, sequentially laminated on another part of the back surface. Each of the first and second electrode layers comprises a base conductive layer and a plating layer covering the base conductive layer. The base conductive layer comprises a base bus bar part and a plurality of base finger parts. With respect to each one of the plurality of base finger parts, one end part and the other end part in the longitudinal direction are narrower than a middle part.

### CROSS-REFERENCE TO RELATED APPLICATIONS

This application claims benefit of priority to International Patent Application No. PCT/JP2018/020771, filed May 30, 2018, and to Japanese Patent Application No. 2017-130575, filed Jul. 3, 2017, the entire contents of each are incorporated herein by reference.

### BACKGROUND

### Technical Field

The present disclosure relates to a back electrode type (back contact type) solar cell and a solar cell module including the solar cell.

### Background Art

Examples of a solar cell using a semiconductor substrate include a double-sided electrode type solar cell having electrodes formed on the both surfaces of a light reception surface and a back surface, and a back electrode type solar cell having electrodes formed only on the back surface. Since such a double-sided electrode type solar cell has electrodes formed on the light reception surface, the electrodes shield sunlight. On the other hand, such a back electrode type solar cell has no electrode formed on the light reception surface, and thus such a back electrode type solar cell has higher receiving efficiency of sunlight as compared with such a double-sided electrode type solar cell. Japanese Unexamined Patent Application, Publication No. 2014-045124 discloses a back electrode type solar cell.

The solar cell disclosed in Japanese Unexamined Patent Application, Publication No. 2014-045124 includes a comb-shaped conductivity type semiconductor layer and a comb-shaped electrode layer on the back surface. The electrode layer includes a base conductive layer, in which a pattern is formed by a printing method with a conductive paste containing metal powder such as silver, and a plating layer, in which metal such as copper is plated on the base conductive layer by an electrolytic plating method. This enables to reduce the conductive paste containing relatively expensive silver.

### SUMMARY

In the case where an electrolytic plating method is used on the back electrode type solar cell, the electrode layer in the peripheral portions of the semiconductor substrate is formed thicker than the electrode layer in the central portion. Such a phenomenon may cause short circuit between the electrodes of heteropolarity alternately arranged in a comb-teeth shape. As a result, the yield decreases. The back electrode type solar cell has the electrode layer formed only on the back surface, and thus the semiconductor substrate may warp. If the semiconductor substrate warps excessively, the semiconductor substrate may be cracked, or the electrode layer may be peeled off. As a result, the yield decreases.

Accordingly, the present disclosure provides a back electrode type solar cell and a solar cell module which is suppressed in decrease of the yield due to short circuit of electrodes or warp of a semiconductor substrate.

The solar cell according to the present disclosure is a back electrode type solar cell provided with a semiconductor substrate, a first conductivity type semiconductor layer and a first electrode layer sequentially laminated on a part of a back surface of the semiconductor substrate, and a second conductivity type semiconductor layer and a second electrode layer sequentially laminated on an other part of the back surface of the semiconductor substrate. Each one of the first electrode layer and the second electrode layer includes a base conductive layer and a plating layer covering the base conductive layer. The base conductive layer includes a base bus bar part, and a plurality of base finger parts arranged along a longitudinal direction of the base bus bar part so as to intersect the base bus bar part. With respect to each one of the plurality of base finger parts, one end part and other end part in a longitudinal direction of the base finger part are narrower than a middle part between the one end part and the other end part.

The solar cell module according to the present disclosure includes the above-described solar cell.

The present disclosure enables to provide a back electrode type solar cell and a solar cell module which is suppressed in decrease of the yield due to short circuit of electrodes or warp of a semiconductor substrate.

### BRIEF DESCRIPTION OF THE DRAWINGS

FIG. 1 is a side view illustrating one example of a solar cell module according to the present embodiment;

FIG. 2 shows a solar cell according to the present embodiment as viewed from the back surface side;

FIG. 3 is a cross-sectional view taken along a line of the solar cell shown in FIG. 2;

FIG. 4 shows base conductive layers in a region A shown in FIG. 2;

FIG. 5 is a cross-sectional view taken along a line V-V, of the base conductive layers shown in FIG. 4;

FIG. 6 is a diagram for explaining an electrolytic plating method;

FIG. 7 is a diagram for explaining a method of applying an electric field in the electrolytic plating method;

FIG. 8 shows base conductive layers of a solar cell according to a modification;

FIG. 9 is a cross-sectional view taken along a line IX-IX, of the base conductive layers shown in FIG. 8; and

FIG. 10 is a cross-sectional view of a first electrode layer of the solar cell according to the modification.

### DETAILED DESCRIPTION

Some embodiments according to the present disclosure will be described below by referring to the accompanying drawings. It is noted that, in the drawings, the same or corresponding parts are denoted by the same reference numerals. For the sake of convenience, hatching, member reference numerals, etc. may be omitted. However, in such cases, other drawings shall be referred to.

### (Solar Cell Module)

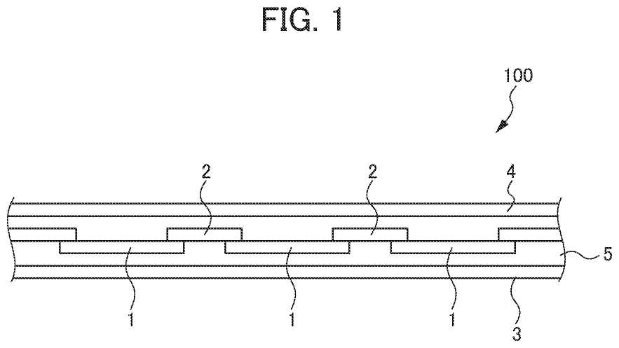

FIG. 1 is a side view illustrating one example of a solar cell module according to the present embodiment. As shown in FIG. 1, a solar cell module 100 includes a plurality of solar cells 1 arranged in a two-dimensional form.

The solar cells 1 are connected in series and/or in parallel by wiring members 2. Specifically, each of the wiring members 2 is connected to a bus bar part or a pad part (to be described below) in an electrode of each of the solar cells 1. The wiring member 2 is a known interconnector, for example, a tab.

The solar cells 1 and the wiring members 2 are sandwiched by a light reception surface protective member 3 and a back surface protective member 4. The space between the light reception surface protective member 3 and the back surface protective member 4 is filled with a liquid or solid sealing material 5, whereby the solar cells 1 and the wiring members 2 are sealed. The light reception surface protective member 3 is, for example, a glass substrate, and the back surface protective member 4 is a glass substrate or a metal plate. The sealing material 5 is made of, for example, transparent resin. The solar cell (hereinafter, referred to as a solar cell) 1 will be described below in detail.

### (Solar Cell)

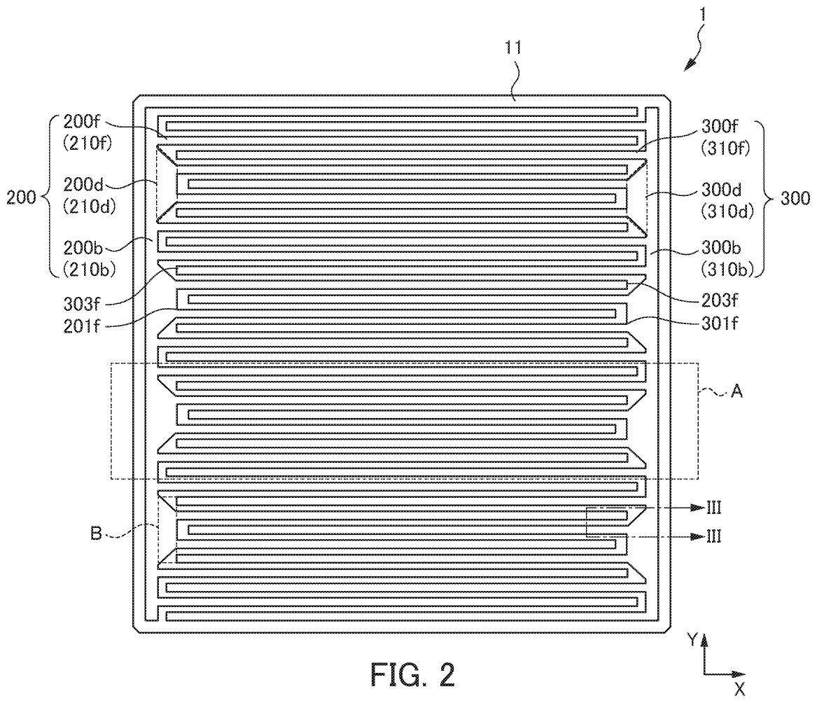

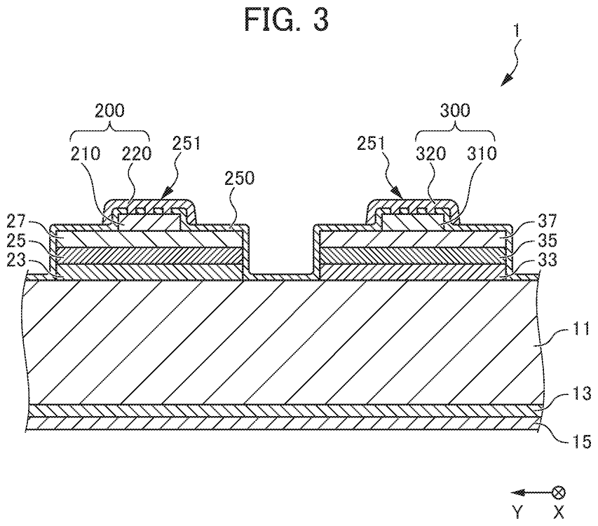

FIG. 2 shows the solar cell according to the present embodiment, as viewed from the back surface side. FIG. 3 is a cross-sectional view taken along a line of the solar cell shown in FIG. 2. The solar cell 1 shown in FIG. 2 and FIG. 3 is a back electrode type solar cell. The solar cell 1 includes a semiconductor substrate 11, and a junction layer 13 and an anti-reflective layer 15 which are sequentially laminated on the light reception surface of the semiconductor substrate 11. The solar cell 1 further includes a junction layer 23, a first conductivity type semiconductor layer 25, a transparent electrode layer 27 and a first electrode layer 200, which are sequentially laminated on a part of the back surface of the semiconductor substrate 11. The solar cell 1 further includes a junction layer 33, a second conductivity type semiconductor layer 35, a transparent electrode layer 37 and a second electrode layer 300, which are sequentially laminated on another part of the back surface of the semiconductor substrate 11.

### <Semiconductor Substrate>

A conductive single crystal silicon substrate, for example, an n-type single crystal silicon substrate or a p-type single crystal silicon substrate is used as the semiconductor substrate 11. This enables to provide higher photoelectric conversion efficiency. The semiconductor substrate 11 is preferably an n-type single crystal silicon substrate. In an n-type single crystalline silicon substrate, a carrier lifetime is longer. This is because, in a p-type single crystal silicon substrate, LID (light induced degradation) may occur, in which light irradiation affects boron (B), which is a p-type dopant, and thereby a carrier becomes a recombination center, and on the other hand, in an n-type single crystal silicon substrate, LID is further suppressed from occurring.

The thickness of the semiconductor substrate 11 is preferably between 50 μm and 250 μm inclusive, more preferably between 60 μm and 200 μm inclusive, and still more preferably between 70 μm and 180 μm inclusive. This reduces costs of material. From the viewpoint of light confinement, the semiconductor substrate 11 preferably has an uneven structure called a texture structure on the plane of light incidence.

It is noted that, as the semiconductor substrate 11, a conductive polycrystalline silicon substrate may be used, for example, an n-type polycrystalline silicon substrate or a p-type polycrystalline silicon substrate. In this case, a solar cell is produced at lower costs.

### <Anti-Reflective Layer>

The anti-reflective layer 15 is formed on the light reception surface of the semiconductor substrate 11 via the junction layer 13. The junction layer 13 is formed as an intrinsic silicon-based layer. A translucent film having a refractive index of approximately 1.5 to 2.3 inclusive is preferably used as the anti-reflective layer 15. As material of the anti-reflective layer 15, SiO, SiN, SiON or the like is preferable. Although the method of forming the anti-reflective layer 15 is not limited to a specific method, a CVD method is preferably used, which allows to precisely control film thickness. The film formation by the CVD method allows to control film quality by controlling material gas or conditions for film formation.

In the present embodiment, the light reception surface has no electrode formed (back electrode type), and such a solar cell has higher receiving efficiency of sunlight, and thus the photoelectric conversion efficiency thereof is high.

### <First Conductivity Type Semiconductor Layer and Second Conductivity Type Semiconductor Layer>

The first conductivity type semiconductor layer 25 is formed on a part of the back surface of the semiconductor substrate 11 via the junction layer 23. The second conductivity type semiconductor layer 35 is formed on another part of the back surface of the semiconductor substrate 11 via the junction layer 33. Each of the first conductivity type semiconductor layer 25 and the second conductivity type semiconductor layer 35 is formed in a comb shape on the back surface of the semiconductor substrate 11, and the comb-teeth portions of the first conductivity type semiconductor layer 25 and the comb-teeth portions of the second conductivity type semiconductor layer 35 are formed so as to be alternately arranged.

The first conductivity type semiconductor layer 25 is formed as a first conductivity type silicon-based layer, for example, a p-type silicon-based layer. The second conductivity type semiconductor layer 35 is formed as a second conductivity type silicon-based layer, for example, an n-type silicon-based layer, which is different from the first conductivity type. It is noted that the first conductivity type semiconductor layer 25 may be an n-type silicon-based layer, and the second conductivity type semiconductor layer 35 may be a p-type silicon-based layer. Each of the p-type silicon-based layer and the n-type silicon-based layer is formed of an amorphous silicon layer or a microcrystal silicon layer containing amorphous silicon and crystal silicon. Boron (B) is preferably used as dopant impurities in the p-type silicon-based layer, and phosphorus (P) is preferably used as dopant impurities in the n-type silicon-based layer.

Although the method of forming the first conductivity type semiconductor layer 25 and the second conductivity type semiconductor layer 35 is not limited to a specific method, the CVD method is preferably used. In an example, SiH₄ gas is preferably used as material gas, and hydrogen-diluted B₂H₆ or PH₃ is preferably used as dopant addition gas. A very small quantity of impurities of, for example, oxygen or carbon may be added in order to improve light transmittance. In this case, gas, for example, CO₂ or CH₄ is introduced during the film formation by the CVD method.

In the case of the back electrode type solar cell, the first conductivity type semiconductor layer 25 and the second conductivity type semiconductor layer 35 are formed on the same plane, in order to receive light on the light reception surface and collect the generated carriers on the back surface. As the method of forming the first conductivity type semiconductor layer 25 and the second conductivity type semiconductor layer 35 on the same plane, the CVD method or an etching method using a mask is available.

### <Junction Layer>

The junction layers 23, 33 are formed as intrinsic silicon-based layers. The junction layers 23, 33 function as passivation layers, and suppress carrier recombination.

### <Transparent Electrode Layer>

The transparent electrode layer 27 is formed on the first conductivity type semiconductor layer 25. The transparent electrode layer 37 is formed on the second conductivity type semiconductor layer 35. Each of the transparent electrode layers 27, 37 are formed as the transparent conductive layer made of a transparent conductive material. As a transparent conductive material, transparent conductive metal oxide is used, for example, indium oxide, tin oxide, zinc oxide, titanium oxide and the complex oxide thereof. The indium-based complex oxide mainly containing indium oxide is preferably used out of them. Indium oxide is particularly preferably used, from the viewpoint of high conductivity and transparency. Furthermore, it is preferable to add dopant to indium oxide in order to ensure reliability or higher conductivity. Examples of the dopant include Sn, W, Zn, Ti, Ce, Zr, Mo, Al, Ga, Ge, As, Si and S. As the method of forming such transparent electrode layers 27, 37, a physical vapor deposition method such as a sputtering method or a chemical vapor deposition method using a reaction of an organometallic compound with oxygen or water, or the like is used.

### <First Electrode Layer and Second Electrode Layer>

The first electrode layer 200 is formed on the transparent electrode layer 27. The second electrode layer 300 is formed on the transparent electrode layer 37.

### <<Planar Structure>>

As shown in FIG. 2, the first electrode layer 200, which is a so-called comb-shaped electrode, has a plurality of finger parts 200f which correspond to comb teeth and extend in a first direction X, and a bus bar part 200b which corresponds to the supporting part of the comb teeth and extends in a second direction Y intersecting the first direction X. The first electrode layer 200 further has a pad part 200d. Similarly, the second electrode layer 300, which is a so-called comb-shaped electrode, has a plurality of finger parts 300f which correspond to comb teeth and extend in the first direction X, and a bus bar part 300b which corresponds to the supporting part of the comb teeth and extends in the second direction Y. The second electrode layer 300 further has a pad part 300d.

In the first electrode layer 200, the bus bar part 200b extends along one peripheral portion of the semiconductor substrate 11, and the finger parts 200f extend from the bus bar part 200b in the direction intersecting the bus bar part 200b. Similarly, in the second electrode layer 300, the bus bar part 300b extends along the other peripheral portion facing the one peripheral portion of the semiconductor substrate 11, and the finger parts 300f extend from the bus bar part 300b in the direction intersecting the bus bar part 300b. The finger parts 200f and the finger parts 300f are alternately arranged in the longitudinal direction of the bus bar parts 200b, 300b.

A plurality of the pad parts 200d are arranged at substantially equal intervals along the longitudinal direction of the bus bar part 200b. Each of the pad parts 200d is located in the first direction X between the bus bar part 200b and a proximal end 201f which is located closest to the bus bar part 200b in each of the finger parts 200f. The width of each of the pad parts 200d (the width in the second direction Y) is wider than the width of the proximal end 201f (line width: the width in the second direction Y) of each of the finger parts 200f. Each of the pad parts 200d is arranged adjacent in the first direction X to a distal end 303f which is located farthest from the bus bar part 300b in each of the finger parts 300f of heteropolarity. Similarly, a plurality of the pad parts 300d are arranged at substantially equal intervals along the longitudinal direction of the bus bar part 300b. Each of the pad parts 300d is located in the first direction X between the bus bar part 300b and a proximal end 301f which is located closest to the bus bar part 300b in each of the finger parts 300f. The width of each of the pad parts 300d (the width in the second direction Y) is wider than the width of the proximal end 301f (line width: the width in the second direction Y) of each of the finger parts 300f. Each of the pad parts 300d is arranged adjacent in the first direction X to a distal end 203f which is located farthest from the bus bar part 200b in each of the finger parts 200f of heteropolarity.

The pad parts 200d, 300d are preferably connected to the wiring members 2 such as tab wires when a module is configured as shown in FIG. 1. The pad parts 200d, 300d may be used as feeding points when a plating layer is formed by an electrolytic plating method. Since the connection to a tab wire or the power supply in the electrolytic plating method requires sufficiently large electrodes, the widths of the pad parts 200d, 300d (the widths in the second direction Y) are preferably wider than the widths of the finger parts 200f, 300f (line widths: the widths in the second direction Y) and the widths of the bus bar parts 200b, 300b (line widths: the widths in the first direction X). The shape of each of the pad parts 200d, 300d is preferably a rectangle or a square having side lengths of 1 mm to 10 mm inclusive, preferably 2 mm to 6 mm inclusive. More preferably, the shape of each of the pad parts 200d, 300d is a trapezoid or a triangle as shown in FIG. 2. For example, the formation of the pad parts 200d decreases the area of the second conductivity type semiconductor layer 35 of heteropolarity. In this regard, the formation of the pad parts 200d in trapezoidal shapes or triangular shapes suppresses the decrease of the area of the second conductivity type semiconductor layer 35, as compared with the case of the formation in rectangular shapes or square shapes (a broken line B). This suppresses the decrease in the photoelectric conversion efficiency caused by the formation of the pad part.

### <<Layer Structure>>

As shown in FIG. 3, the first electrode layer 200 has a multilayer structure, including a base conductive layer 210, a plating layer 220 covering the base conductive layer 210, and an insulating layer 250 laminated between the base conductive layer 210 and the plating layer 220. Similarly, the second electrode layer 300 has a multilayer structure, including a base conductive layer 310, a plating layer 320 covering the base conductive layer 310, and the insulating layer 250 laminated between the base conductive layer 310 and the plating layer 320.

### <<<Base Conductive Layer>>>

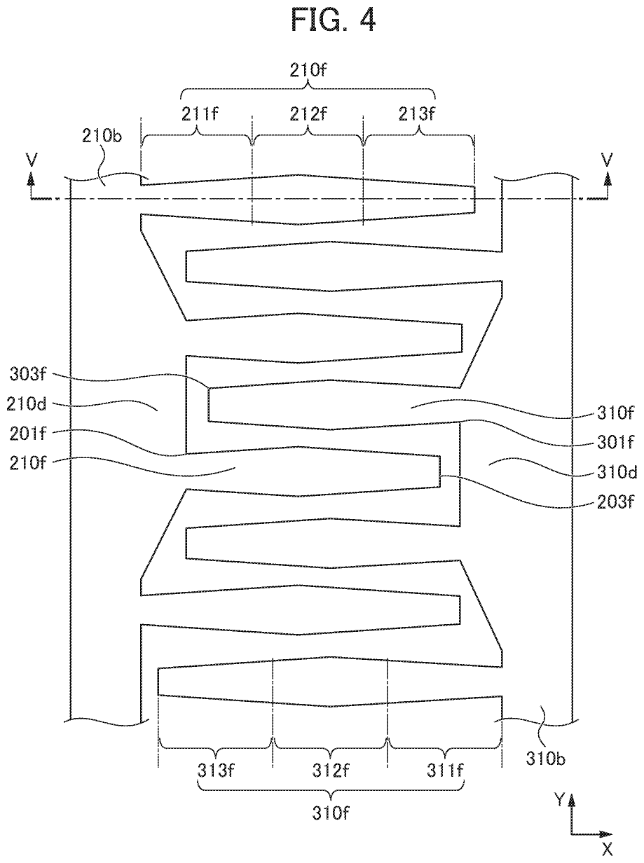

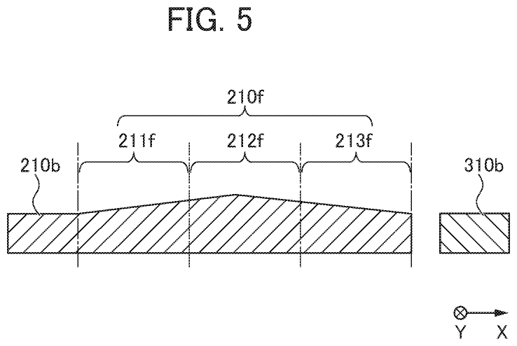

FIG. 4 shows the base conductive layers in a region A shown in FIG. 2. FIG. 5 is a cross-sectional view taken along a line V-V, of the base conductive layers shown in FIG. 4. Each of FIG. 4 and FIG. 5 schematically shows the base conductive layers 210, 310, wherein the dimensions thereof are adjusted in a manner easy to be observed for the sake of convenience. In FIG. 4 and FIG. 5, the base conductive layer 210 in the bus bar part 200b of the first electrode layer 200 is referred to as a base bus bar part 210b. The base conductive layer 210 in each of the finger parts 200f of the first electrode layer 200 is referred to as a base finger part 210f. The base conductive layer 310 in the bus bar part 300b of the second electrode layer 300 is referred to as a base bus bar part 310b. The base conductive layer 310 in each of the finger parts 300f of the second electrode layer 300 is referred to as a base finger part 310f. The base conductive layer 210 in each of the pad parts 200d of the first electrode layer 200 is referred to as a base pad part 210d. The base conductive layer 310 in each of the pad parts 300d of the second electrode layer 300 is referred to as a base pad part 310d.

As shown in FIG. 4, the base finger part 210f has one end part 211f, an intermediate part (middle part) 212f, and the other end part 213f, which are the ones obtained by being equally divided into three parts in the longitudinal direction (the first direction X). The base finger part 210f is formed so that the width (the width in the second direction Y) is gradually decreased from the intermediate part 212f toward the one end part 211f and the other end part 213f. As shown in FIG. 5, the base finger part 210f is formed so that the thickness is gradually decreased from the intermediate part 212f toward the one end part 211f and the other end part 213f. Accordingly, the widths of the one end part 211f and the other end part 213f of the base finger part 210f are narrower than the width of the intermediate part 212f. The thicknesses of the one end part 211f and the other end part 213f of the base finger part 210f are thinner than the thickness of the intermediate part 212f. That is, the one end part 211f and the other end part 213f of the base finger part 210f are narrower than the intermediate part 212f. In other words, the volume of the one end part 211f of the base finger part 210f and the volume of the other end part 213f are smaller than the volume of the intermediate part 212f.

Similarly, as shown in FIG. 4, the base finger part 310f has one end part 311f, an intermediate part (middle part) 312f and the other end part 313f, which are the ones obtained by being equally divided into three parts in the longitudinal direction (the first direction X). The base finger part 310f is formed so that the width (the width in the second direction Y) is gradually decreased from the intermediate part 312f toward the one end part 311f and the other end part 313f. As shown in FIG. 5, the base finger part 310f is formed so that the thickness is gradually decreased from the intermediate part 312f toward the one end part 311f and the other end part 313f. Accordingly, the widths of the one end part 311f and the other end part 313f of the base finger part 310f are narrower than the width of the intermediate part 312f. The thicknesses of the one end part 311f and the other end part 313f of the base finger part 310f are thinner than the thickness of the intermediate part 312f. That is, the one end part 311f and the other end part 313f of the base finger part 310f are narrower than the intermediate part 312f. In other words, the volume of the one end part 311f of the base finger part 310f and the volume of the other end part 313f are smaller than the volume of the intermediate part 312f.

The width of the intermediate part 212f of the base finger part 210f and the width of the intermediate part 312f of the base finger part 310f are preferably between 100 μm and 500 μm inclusive. The widths of the one end part 211f and the other end part 213f of the base finger part 210f and the widths of the one end part 311f and the other end part 313f of the base finger part 310f are preferably between 20 μm and 300 μm inclusive. The thickness of the intermediate part 212f of the base finger part 210f and the thickness of the intermediate part 312f of the base finger part 310f are preferably between 10 μm and 50 μm inclusive. The thicknesses of the one end part 211f and the other end part 213f of the base finger part 210f and the thicknesses of the one end part 311f and the other end part 313f of the base finger part 310f are preferably between 3 μm and 30 μm inclusive. The center distance between the base finger part 210f and the base finger part 310f is preferably between 100 μm and 1000 μm inclusive.

The above-described pad parts 200d, 300d are to be described below in other words by referring to FIG. 2 and FIG. 4. A plurality of the base pad parts 210d are arranged at substantially equal intervals along the longitudinal direction of the base bus bar part 210b. Each of the base pad parts 210d is located in the first direction X between the base bus bar part 210b and the proximal end 201f which is located closest to the base bus bar part 210b in the base finger part 210f. The width of each of the base pad parts 210d (the width in the second direction Y) is wider than the width of the proximal end 201f (line width: the width in the second direction Y) of the base finger part 210f. Each of the base pad parts 210d is arranged adjacent in the first direction X to the distal end 303f which is located farthest from the base bus bar part 310b in the base finger part 310f of heteropolarity. Similarly, a plurality of the base pad parts 310d are arranged at substantially equal intervals along the longitudinal direction of the base bus bar part 310b. Each of the base pad parts 310d is located in the first direction X between the base bus bar part 310b and the proximal end 301f which is located closest to the base bus bar part 310b in the base finger part 310f. The width of each of the base pad parts 310d (the width in the second direction Y) is wider than the width of the proximal end 301f (line width: the width in the second direction Y) of the base finger part 310f. Each of the base pad parts 310d is arranged adjacent in the first direction X to the distal end 203f which is located farthest from the base bus bar part 210b in the base finger part 210f of heteropolarity.

The base conductive layer 210 of the first electrode layer 200 and the base conductive layer 310 of the second electrode layer 300 are formed of a conductive paste containing silver powder having a particle size of 0.5 μm to 20 μm inclusive, and silver particles having a particle size of 200 nm or less. The usage of such a conductive paste as described above, containing not only the silver powder having a particle size of 0.5 μm to 20 μm inclusive, but also the silver particles having a particle size of 200 nm or less which is smaller than the particle size of the silver powder, enhances the filling property of filler, thereby lowering the resistance of the base conductive layers 210, 310. Accordingly, even in the case where the one end part 211f and the other end part 213f of the base finger part 210f and the one end part 311f and the other end part 313f of the base finger part 310f are formed narrower in width and thinner in thickness, the one end parts 211f, 311f and the other end parts 213f, 313f are suppressed in increase of the resistance.

With regard to the silver powder (PO) and the silver particles (PA), the ratio PO/PA therebetween is preferably 2/8≤PO/PA≤8/2. Under such a ratio PO/PA, the filling property of filler is particularly enhanced, and the resistance of the base conductive layers 210, 310 is lowered.

The conductive paste of forming the base conductive layers 210, 310 may contain copper powder having a particle size of 0.5 μm to 10 μm inclusive with the surface layer plated with noble metal, instead of silver powder. Alternatively, the conductive paste of forming the base conductive layers 210, 310 may contain not only silver powder and silver particles, but also the copper powder having a particle size of 0.5 μm to 10 μm inclusive with the surface layer plated with noble metal. The plating of covering the surface layer preferably contains at least one of silver, platinum, gold and palladium. The usage of the conductive paste containing the copper powder with the surface layer plated with noble metal lowers the resistance of the conductive paste, and further reduces the costs of material.

### <<<Plating Layer>>>

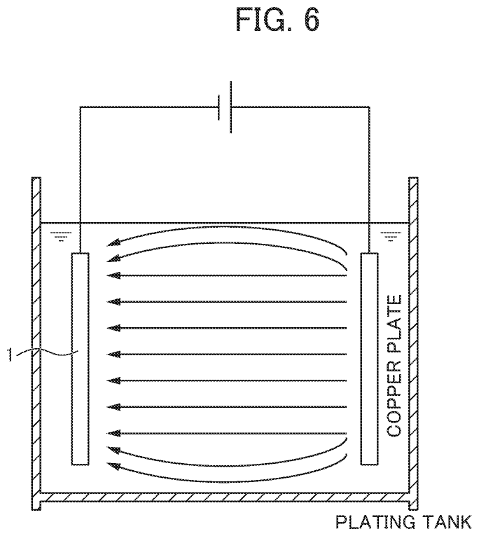

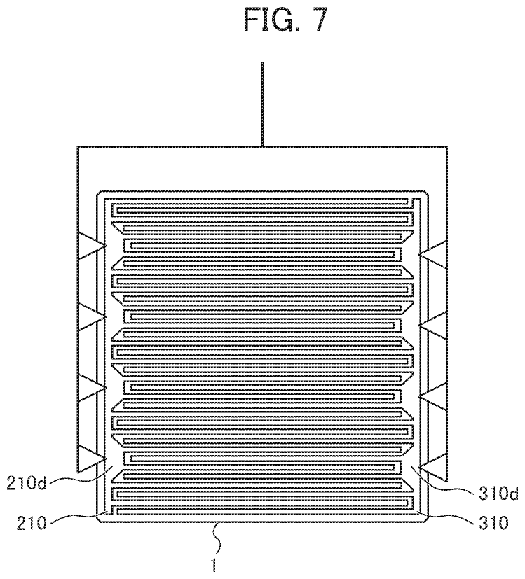

Referring to FIG. 3, the plating layer 220 is formed so as to cover the base conductive layer 210, and the plating layer 320 is formed so as to cover the base conductive layer 310. The plating layers 220, 320 are formed by an electrolytic plating method, particularly an electrolytic plating method using copper. Specifically, as shown in FIG. 6, an electric field is applied to the base conductive layer 210 of the first electrode layer 200 and the base conductive layer 310 of the second electrode layer 300, thereby selectively forming the plating layers 220, 320 on the base conductive layers 210, 310. In this case, as shown in FIG. 7, an electric field is applied to the base conductive layer 210 and the base conductive layer 310 by use of the base pad part 210d of the base conductive layer 210 and the base pad part 310d of the base conductive layer 310. As described above, the first electrode layer 200 and the second electrode layer 300 are formed by laminating the plating layers 220, 320 on the silver paste of forming the base conductive layers 210, 310, whereby the use amount of the silver paste containing relatively expensive silver is reduced.

### <<<Insulating Layer>>>

The insulating layer 250 is formed so as to cover the entire back surface of the solar cell 1 excluding the plating layer 220 of the first electrode layer 200 and the plating layer 320 of the second electrode layer 300. The insulating layer 250 is also formed between the base conductive layer 210 and the plating layer 220 in the first electrode layer 200 and between the base conductive layer 310 and the plating layer 320 in the second electrode layer 300. In the present embodiment, at least one opening 251 is formed in a part of the insulating layer 250, and the opening 251 is filled with the material of the plating layer 220 or the plating layer 320. As a result, the base conductive layer 210 and the plating layer 220 are connected physically and electrically, and the base conductive layer 310 and the plating layer 320 are connected physically and electrically.

It is noted that the insulating layer 250 may have a very thin film portion having a thickness of approximately several nanometers (that is, locally having the region where the film thickness is thin), whereby the base conductive layer 210 and the plating layer 220 are connected electrically, and the base conductive layer 310 and the plating layer 320 are connected electrically.

The method of forming the opening 251 in the insulating layer 250 is not limited to a specific method. Laser irradiation, mechanical drilling, chemical etching or the like can be adopted as the method. As another method of forming an opening, the base conductive layers 210, 310 may be formed to have larger uneven surface structures than the uneven surface structure of the photoelectric converter (the semiconductor substrate 11, the first conductivity type semiconductor layer 25, and the second conductivity type semiconductor layer 35), and an opening may be formed at the time of forming an insulating layer. As the method of forming an opening of one embodiment, the conductive material in the base conductive layers 210, 310 is heated (annealed) and fluidized, thereby forming the opening 251 in the insulating layer 250 formed on the base conductive layers 210, 310.

As the material of the insulating layer 250, material having electrical insulation property is used. The material of the insulating layer 250 is preferably the material having chemical stability against a plating solution. In the case where a plating method is adopted to form the plating layers 220, 320, the insulating layer 250 made of such material is hardly dissolved during the plating step, and thus damage to the surface of the photoelectric converter hardly occurs. In the case where the insulating layer 250 is formed also on the region where the base conductive layers 210, 310 are not formed, the insulating layer 250 preferably has good adhesive strength with the photoelectric converter. The transparent electrode layers 27, 37 and the insulating layer 250 are adhered strongly, whereby the insulating layer 250 hardly peels off during the plating step, and metal is prevented from depositing on the transparent electrode layers 27, 37. Further, the base conductive layers 210, 310 are prevented from peeling off from the semiconductor substrate 11.

The insulating layer 250 is preferably made of material having low light absorption. Since the insulating layer 250 is formed on the back surface of the solar cell 1, the insulating layer 250 is not directly irradiated with light but is irradiated with the reflection light from the back surface protective member 4 such as a back sheet in the solar cell module 100 shown in FIG. 1. In the case where the insulating layer 250 absorbs less light, the photoelectric converter is able to acquire more light.

The insulating layer 250 is made of any material regardless of an inorganic insulating material or an organic insulating material, as long as the material has high adhesion with the base conductive layers 210, 310 and the plating layers 220, 320. Examples of an inorganic insulating material include silicon oxide, silicon nitride, titanium oxide, aluminum oxide, magnesium oxide, and zinc oxide. Examples of an organic insulating material include polyester, ethylene-vinyl acetate copolymer, acrylic, epoxy, and polyurethane.

The insulating layer 250 may be formed by a known method. In the case of an inorganic insulating material such as silicon oxide or silicon nitride, dry process such as a plasma CVD method or a sputtering method is preferable. In the case of an organic insulating material, wet process such as a spin coating method or a screen printing method is preferable. These methods enable to form a film having a dense structure with few defects such as pinholes.

The insulating layer 250 is preferably formed by a plasma CVD method out of these methods, from the viewpoint of forming a film having a denser structure. This method enables to form the insulating layer 250 having a highly dense structure, not only the case of a thick film having a thickness of approximately 200 nm, but also the case of a thin film having a thickness of approximately 30 nm to 100 nm inclusive.

For example, in the case of the photoelectric converter having a texture structure (uneven structure) surface, the insulating layer 250 is preferably formed by a plasma CVD method from the viewpoint of forming a film with high accuracy on the recesses or protrusions of the texture structure. The use of such a highly dense insulating layer decreases damage to the transparent electrode layers 27, 37 at the time of plating, and further prevents metal from depositing on the transparent electrode layers 27, 37. Such a highly dense insulating film is capable of further functioning as a barrier layer against water, oxygen or the like for the layers inside the photoelectric converter, thereby improving long term reliability of the solar cell.

It is noted that, when the electrolytic plating method is performed, the electric field tends to concentrate on the peripheral portions of the semiconductor substrate as illustrated by arrows in FIG. 6, and thus such a phenomenon occurs that the plating layers in the peripheral portions of the semiconductor substrate are formed thicker than the plating layers in the central portion of the semiconductor substrate. In this case, when the base finger parts are formed to have constant widths and thicknesses, the first electrode layer and the second electrode layer that are alternately arranged in a comb-teeth shape may be short circuited in the peripheral portions of the semiconductor substrate. In this regard, the solar cell 1 according to the present embodiment has the one end part 211f and the other end part 213f narrower in width than the intermediate part 212f, of each of the base finger parts 210f of the base conductive layer 210 in the first electrode layer 200. The solar cell 1 has the one end part 311f and the other end part 313f narrower in width than the intermediate part 312f, of each of the base finger parts 310f of the base conductive layer 310 in the second electrode layer 300. Thus, even if the both end parts of the plating layers 220, 320 are formed thick in the finger parts 200f of the first electrode layer 200 and the finger parts 300f of the second electrode layer 300, the both end parts of the finger parts 200f of the first electrode layer 200 each including the base conductive layer 210 and the plating layer 220, and the both end parts of the finger parts 300f of the second electrode layer 300 each including the base conductive layer 310 and the plating layer 320 are hardly formed thick. This suppresses short circuit from occurring between the first electrode layer 200 and the second electrode layer 300 alternately arranged in a comb-teeth shape and suppresses decrease of the yield. It is noted that the electrode structure according to the present embodiment also has the effect of preventing short circuit caused by adhesion of foreign matter or the like.

In some back electrode type solar cell having electrodes only on the back surface thereof, the semiconductor substrate may warp when the electrode is fired, due to the difference between the linear expansion coefficient of the base conductive layer formed of a conductive paste containing metal powder such as silver and the linear expansion coefficient of the transparent electrode layer such as of ITO. If the semiconductor substrate warps excessively, the semiconductor substrate may be cracked, or the electrode may be peeled off in some cases. As a result, the yield decreases. In this regard, the solar cell 1 according to the present embodiment has the one end part 211f and the other end part 213f thinner in thickness than the intermediate part 212f, of each of the base finger parts 210f of the base conductive layer 210 in the first electrode layer 200. The solar cell 1 has the one end part 311f and the other end part 313f thinner in thickness than the intermediate part 312f, of each of the base finger parts 310f of the base conductive layer 310 in the second electrode layer 300. This suppresses the semiconductor substrate 11 from warping and suppresses decrease of the yield. It is noted that the structure is expected to have the effect of reducing costs by the reduction in thickness of the base conductive layer and the reduction in width of the line thereof.

In the present embodiment, the base conductive layers 210, 310 are formed narrower and thinner in both width and thickness. Alternatively, just forming the base conductive layers 210, 310 narrower or thinner in either one of width or thickness exerts the effect of suppressing decrease of the yield.

In the solar cell 1 according to the present embodiment, the base conductive layer 210 of the first electrode layer 200 and the base conductive layer 310 of the second electrode layer 300 are formed of the conductive paste containing not only the silver powder having a particle size of 0.5 μm to 20 μm inclusive, but also the silver particles having a particle size of 200 nm or less which is smaller than the particle size of the silver powder. This enhances the filing property of filler, thereby lowering the resistance of the base conductive layers 210, 310. The contact resistance with base layers (for example, the transparent electrode layers 27, 37 made of transparent conductive oxide) is also lowered. As a result, even in the case where the one end part 211f and the other end part 213f of each of the base finger parts 210f and the one end part 311f and the other end part 313f of each of the base finger parts 310f are formed narrower in width and thinner in thickness, the one end parts 211f, 311f and the other end parts 213f, 313f are suppressed in increase of the resistance.

### (Modification 1 of Solar Cell)

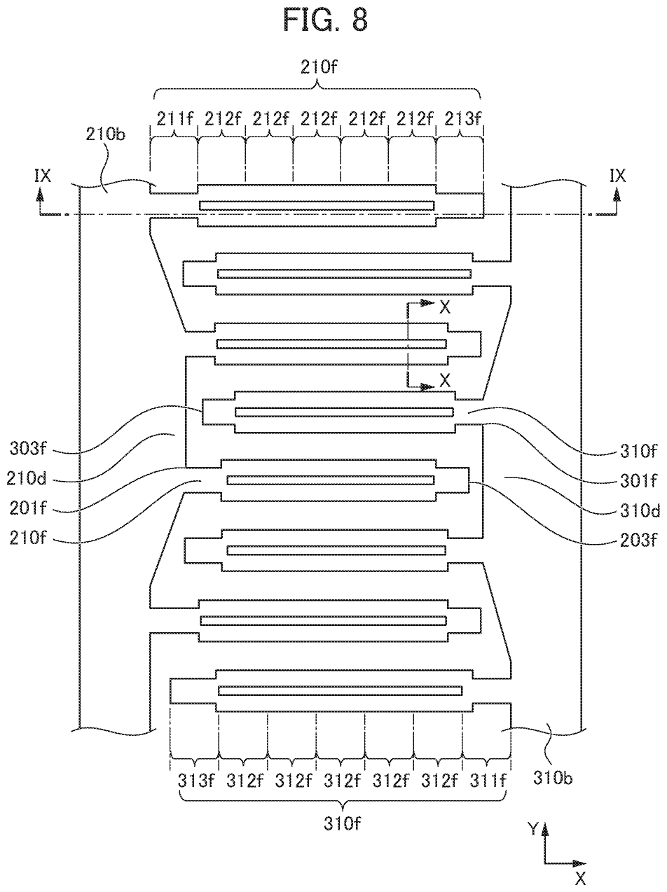

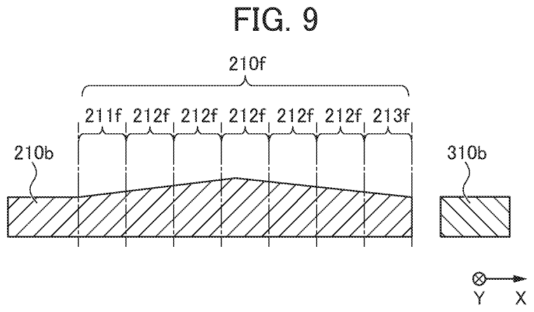

FIG. 8 shows base conductive layers in a solar cell according to a modification of the present embodiment. FIG. 9 is a cross-sectional view taken along a line IX-IX, of the base conductive layers shown in FIG. 8. Each of FIG. 8 and FIG. 9 schematically shows base conductive layers 210, 310, wherein the dimensions thereof are adjusted in a manner easy to be observed for the sake of convenience. As shown in FIG. 8, in a solar cell 1 according to the present embodiment, a base finger part 210f of the base conductive layer 210 in a first electrode layer 200 has one end part 211f and the other end part 213f, which are the ones obtained by being equally divided into seven parts in the longitudinal direction (a first direction X), and a plurality of middle parts 212f arranged between the one end part 211f and the other end part 213f. Each of the middle parts 212f of the base finger part 210f includes two portions separated in the direction (a second direction Y) intersecting the longitudinal direction thereof. Accordingly, the widths (the widths in the second direction Y) of the one end part 211f and the other end part 213f of the base finger part 210f are narrower than the width (the width in the second direction Y) of each of the middle parts 212f. As shown in FIG. 9, the base finger part 210f is formed so that the thickness is gradually decreased from the center toward the one end part 211f and the other end part 213f. Accordingly, the thicknesses of the one end part 211f and the other end part 213f of the base finger part 210f are thinner than the thickness of each of the middle parts 212f. That is, the one end part 211f and the other end part 213f of the base finger part 210f are narrower than the middle parts 212f. In other words, the volume of the one end part 211f and the volume of the other end part 213f of the base finger part 210f are smaller than the volume of each of the intermediate parts 212f.

Similarly, a base finger part 310f of the base conductive layer 310 in a second electrode layer 300 has one end part 311f and the other end part 313f, which are the ones obtained by being equally divided into seven parts in the longitudinal direction (the first direction X), and a plurality of middle parts 312f arranged between the one end part 311f and the other end part 313f. Each of the middle parts 312f of the base finger part 310f includes two portions separated in the direction (the second direction Y) intersecting the longitudinal direction thereof. Accordingly, the widths (the widths in the second direction Y) of the one end part 311f and the other end part 313f of the base finger part 310f are narrower than the width (the width in the second direction Y) of each of the middle parts 312f. The base finger part 310f is formed so that the thickness is gradually decreased from the center toward the one end part 311f and the other end part 313f. Accordingly, the thicknesses of the one end part 311f and the other end part 313f of the base finger part 310f are thinner than the thickness of each of the middle parts 312f. That is, the one end part 311f and the other end part 313f of the base finger part 310f are narrower than each of the middle parts 312f. In other words, the volume of the one end part 311f and the volume of the other end part 313f of the base finger part 310f are smaller than the volume of each of the intermediate parts 312f.

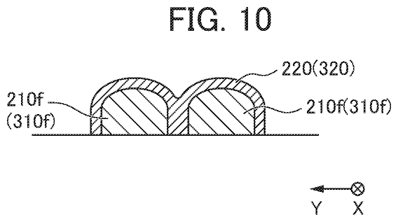

FIG. 10 is a cross-sectional view taken along a line X-X of the base conductive layer shown in FIG. 8 and shows the cross section of the first electrode layer corresponding to the middle part of the base finger part of the base conductive layer. As shown in FIG. 10, one line of the first electrode layer 200 is formed, by laminating a plating layer 220 in the space between the two portions of each of the middle parts 212f of the base finger part 210f of the base conductive layer 210. Similarly, one line of the second electrode layer 300 is formed, by laminating a plating layer 320 in the space between the two portions of each of the middle parts 312f of the base finger part 310f of the base conductive layer 310.

Such formation of the first electrode layer 200 and the second electrode layer 300 enables to reduce the use amount of the silver paste of forming the base conductive layers 210, 310 and containing relatively expensive silver. The middle parts 212f, 312f of the base finger parts 210f, 310f of the first electrode layer 200 and the second electrode layer 300, respectively, are able to be formed wider in width, whereby the adhesion between the first electrode layer 200 and the base layer thereof and between the second electrode layer 300 and the base layer thereof is improved (the performance is improved by improved contact resistance, and the yield is improved by higher adhesion).

### (Modification 2 of Solar Cell)

In the present embodiment, a plurality of base finger parts 210f, 310f may be arranged in the direction (a second direction Y) intersecting the longitudinal direction of the base finger parts 210f, 310f, and in the plurality of base finger parts 210f, 310f, the widths in the direction (the second direction Y) of the base finger parts 210f, 310f in one peripheral portion and the other peripheral portion of the semiconductor substrate 11 may be formed narrower than the widths of the base finger parts 210f, 310f of the middle parts between the one peripheral portion and the other peripheral portion. The thicknesses of the base finger parts 210f, 310f in the one peripheral portion and the other peripheral portion of the semiconductor substrate 11 may be formed thinner than the thicknesses of the base finger parts 210f, 310f of the middle parts therebetween. That is, the base finger parts 210f, 310f in the one peripheral portion and the other peripheral portion of the semiconductor substrate 11 may be formed narrower than the base finger parts 210, 310f of the middle parts therebetween.

Thus, even if the plating layers 220, 320 are formed thick in the base finger parts 210f, 310f in the peripheral portions of the semiconductor substrate 11 in the direction (the second direction Y) intersecting the longitudinal direction of the base finger parts 210f, 310f, the first electrode layer 200 including the base conductive layer 210 and the plating layer 220 and the second electrode layer 300 including the base conductive layer 310 and the plating layer 320 are hardly formed thick in the peripheral portions of the semiconductor substrate 11. This suppresses short circuit from occurring between the first electrode layer 200 and the second electrode layer 300 alternately arranged in a comb shape and suppresses decrease of the yield.

The thicknesses of the base finger parts 210f, 310f are thin in the peripheral portions of the semiconductor substrate 11 in the direction (the second direction Y) intersecting the longitudinal direction of the base finger part 210f. This suppresses the semiconductor substrate 11 from warping, and thus suppresses decrease of the yield.

### (Modification 3 of Solar Cell)

In the present embodiment, as shown in FIG. 3, the first electrode layer 200 and the second electrode layer 300 include the insulating layer 250 having the opening 251, and selectively include the plating layers 220, 320 in the opening 251, that is, on the base conductive layers 210, 310, by an electrolytic plating method. However, the solar cell 1 may not include the insulating layer 250. In an example, a first electrode layer 200 and a second electrode layer 300 may be formed, by selectively forming plating layers 220, 320 on base conductive layers 210, 310 while protecting a photoelectric converter by a known resist technique (masking technique).

Even in this case, in an example, one end part 211f and the other end part 213f of a base finger part 210f of the base conductive layer 210 in the first electrode layer 200 are formed thinner in thickness, and one end part 311f and the other end part 313f of a base finger part 310f of the base conductive layer 310 in the second electrode layer 300 are formed thinner in thickness, thereby suppressing a semiconductor substrate 11 from warping, and thus suppressing decrease of the yield.

Although the embodiments according to the present disclosure have been described so far, the present disclosure is not limited to the above-described embodiments, and various modifications are available. In the present embodiment, the heterojunction type solar cell as shown in FIG. 1 and FIG. 2 has been described. In an example, the characteristic electrode structure according to the present disclosure may be applied to various types of solar cells such as a homojunction type solar cell, not limited to such a heterojunction type solar cell.

The solar cell according to the present embodiment includes the transparent electrode layer (for example, ITO) between the conductivity type semiconductor layer and the electrode layer. A solar cell may be configured without any transparent electrode layer.

What is claimed is:

1. A solar cell of a back electrode type solar cell, the solar cell comprising:
a semiconductor substrate;
a first conductivity type semiconductor layer and a first electrode layer sequentially laminated on a part of a back surface of the semiconductor substrate; and
a second conductivity type semiconductor layer and a second electrode layer sequentially laminated on an other part of the back surface of the semiconductor substrate, wherein
each one of the first electrode layer and the second electrode layer comprises a base conductive layer and a plating layer covering the base conductive layer,
the base conductive layer comprises a base bus bar part, and a plurality of base finger parts arranged along a longitudinal direction of the base bus bar part so as to intersect the base bus bar part, and
with respect to each one of the plurality of base finger parts, one end part and an other end part in a longitudinal direction of the base finger part are narrower than a middle part between the one end part and the other end part.

2. The solar cell according to claim 1, wherein
each one of the plurality of base finger parts includes the one end part, the other end part and at least one of the middle part obtained by being equally divided into at least three parts in the longitudinal direction of the base finger part, and
a volume of the one end part and a volume of the other end part are smaller than a volume of the at least one of the middle part.

3. The solar cell according to claim 1, wherein with respect to each one of the plurality of base finger parts, at least one of a width and a thickness is gradually decreased from the middle part toward the one end part and the other end part.

4. The solar cell according to claim 1, wherein with respect to each one of the plurality of base finger parts, the middle part includes at least two portions separated in a direction intersecting the longitudinal direction of the base finger part.

5. The solar cell according to claim 1, wherein
with respect to each one of the plurality of base finger parts, one end on the one end part is a proximal end located closest to the base bus bar part, and other end on the other end part is a distal end located farthest from the base bus bar part, and
the base conductive layer includes at least one base pad part located between the proximal end of the base finger part and the base bus bar part, and the at least one base pad part has a width wider than a width of the proximal end.

6. The solar cell according to claim 5, wherein
the base pad part in the first electrode layer and the distal end of the base finger part in the second electrode layer are arranged adjacent to each other, and
the base pad part in the second electrode layer and the distal end of the base finger part in the first electrode layer are arranged adjacent to each other.

7. The solar cell according to claim 5, wherein the base conductive layer includes a plurality of the base pad parts arranged in the longitudinal direction of the base bus bar part.

8. The solar cell according to claim 7, wherein the plurality of base pad parts is arranged at equal intervals.

9. The solar cell according to claim 1, wherein the base conductive layer contains metal powder having a particle size of from 0.5 μm to 20 μm and metal particles having a particle size of 200 nm or less.

10. The solar cell according to claim 9, wherein with respect to the metal powder abbreviated to PO and the metal particles abbreviated to PA, a ratio PO/PA is 2/8≤PO/PA≤8/2.

11. The solar cell according to claim 9, wherein material of the metal powder and the metal particles is silver.

12. The solar cell according to claim 11, wherein the base conductive layer further contains copper powder having a particle size of from 0.5 μm to 10 μm with a surface layer plated with noble metal.

13. The solar cell according to claim 9, wherein
material of the metal particles is silver, and
the metal powder is copper powder having a particle size of from 0.5 μm to 10 μm with a surface layer plated with noble metal.

14. The solar cell according to claim 12, wherein the noble metal contains at least one of silver, platinum, gold and palladium.

15. The solar cell according to claim 1, wherein
an insulating layer is interposed between the base conductive layer and the plating layer, and
the insulating layer includes an opening allowing to physically and electrically connect the base conductive layer and the plating layer.

16. A solar cell module comprising the solar cell according to claim 1.

17. The solar cell according to claim 2, wherein with respect to each one of the plurality of base finger parts, at least one of a width and a thickness is gradually decreased from the middle part toward the one end part and the other end part.

18. The solar cell according to claim 2, wherein with respect to each one of the plurality of base finger parts, the middle part includes at least two portions separated in a direction intersecting the longitudinal direction of the base finger part.

19. The solar cell according to claim 2, wherein
with respect to each one of the plurality of base finger parts, one end on the one end part is a proximal end located closest to the base bus bar part, and other end on the other end part is a distal end located farthest from the base bus bar part, and
the base conductive layer includes at least one base pad part located between the proximal end of the base finger part and the base bus bar part, and the at least one base pad part has a width wider than a width of the proximal end.

20. The solar cell according to claim 6, wherein the base conductive layer includes a plurality of the base pad parts arranged in the longitudinal direction of the base bus bar part.
